(19) United States
(12) Patent Application Publication
(10) Pub. No.: US 2025/0261511 A1
(43) Pub. Date: Aug. 14, 2025

(54) COMPLEMENTARY METAL-OXIDE SEMICONDUCTOR CIRCUIT, METHOD FOR FABRICATING THE SAME, AND ELECTRONIC DEVICE INCLUDING THE COMPLEMENTARY METAL-OXIDE SEMICONDUCTOR CIRCUIT

(71) Applicant: Japan Display Inc., Tokyo (JP)

(72) Inventor: Toshihiko ITOGA, Tokyo (JP)

(73) Assignee: Japan Display Inc., Tokyo (JP)

(21) Appl. No.: 18/983,482

(22) Filed: Dec. 17, 2024

(30) Foreign Application Priority Data
Feb. 8, 2024 (JP) 2024-017642

(51) Int. Cl. H10K 59/121; H10K 59/12

(52) U.S. Cl. CPC H10K 59/1213; H10K 59/1201

(57) ABSTRACT

Disclosed is a complementary metal-oxide semiconductor circuit including a n-type metal-oxide semiconductor thin-film transistor and a p-type metal-oxide semiconductor thin-film transistor. Each of the n-type metal-oxide semiconductor thin-film transistor and the p-type metal-oxide semiconductor thin-film transistor includes a semiconductor film, a gate insulating film over the semiconductor film, a gate electrode over the gate insulating film, an interlayer insulating film over the gate electrode, and a pair of terminals located over the interlayer insulating film and electrically connected to the semiconductor film. The semiconductor film of the p-type metal-oxide semiconductor thin-film transistor includes a fluorine ion.

### CROSS-REFERENCE TO RELATED APPLICATION

This application claims the benefit of priority to Japanese Patent Application No. 2024-017642, filed on Feb. 8, 2024, the entire contents of which are incorporated herein by reference.

### FIELD

An embodiment of the present invention relates to a complementary metal-oxide semiconductor circuit and a method for fabricating the same. Alternatively, an embodiment of the present invention relates to an electronic device including the complementary metal-oxide semiconductor circuit.

### BACKGROUND

Complementary metal-oxide semiconductor circuits (hereinafter, also referred to as CMOS circuits) are circuits containing a p-type metal-oxide semiconductor transistor and a n-type metal-oxide semiconductor transistor electrically connected to each other and are incorporated in a variety of electronic devices. The CMOS circuits are fabricated by using the so-called photolithography process. Japanese laid-open patent publication No. 2010-113151 discloses a method to reduce the number of steps in the photolithography process for fabricating a p-type metal-oxide semiconductor thin-film transistor (hereinafter, also referred to as pMOSTFT) and a n-type metal-oxide semiconductor thin-film transistor (hereinafter, also referred to as nMOSTFT) over a substrate.

### SUMMARY

An embodiment of the present invention is a complementary metal-oxide semiconductor circuit. The complementary metal-oxide semiconductor circuit includes a n-type metal-oxide semiconductor thin-film transistor and a p-type metal-oxide semiconductor thin-film transistor. Each of the n-type metal-oxide semiconductor thin-film transistor and the p-type metal-oxide semiconductor thin-film transistor includes a semiconductor film, a gate insulating film over the semiconductor film, a gate electrode over the gate insulating film, an interlayer insulating film over the gate electrode, and a pair of terminals located over the interlayer insulating film and electrically connected to the semiconductor film. The semiconductor film of the p-type metal-oxide semiconductor thin-film transistor includes a fluorine ion.

An embodiment of the present invention is an electronic device including a complementary metal-oxide semiconductor circuit. The complementary metal-oxide semiconductor circuit includes a n-type metal-oxide semiconductor thin-film transistor and a p-type metal-oxide semiconductor thin-film transistor. Each of the n-type metal-oxide semiconductor thin-film transistor and the p-type metal-oxide semiconductor thin-film transistor includes a semiconductor film, a gate insulating film over the semiconductor film, a gate electrode over the gate insulating film, an interlayer insulating film over the gate electrode, and a pair or terminals located over the interlayer insulating film and electrically connected to the semiconductor film. The semiconductor film of the p-type metal-oxide semiconductor thin-film transistor includes a fluorine ion.

An embodiment of the present invention is a fabrication method of a complementary metal-oxide semiconductor circuit. The fabrication method includes: forming an undercoat over a substrate; forming a first semiconductor film and a second semiconductor film over the undercoat; doping both edge portions of the first semiconductor film with a first dopant imparting n-type conductivity in a state where the second semiconductor film and a region between both the edge portions of the first semiconductor film are masked; doping both edge portions of the second semiconductor film with a second dopant imparting p-type conductivity in a state where the first semiconductor film and a region between both the edge portions of the second semiconductor film are masked; forming a gate insulating film over the first semiconductor film and the second semiconductor film; forming, over the gate insulating film, a first gate electrode overlapping the first semiconductor film and exposing both the edge portions of the first semiconductor film and a second gate electrode overlapping the second semiconductor film and exposing both the edge portions of the second semiconductor film; forming an interlayer insulating film overlapping the first gate electrode and the second gate electrode; and forming, over the interlayer insulating film, a pair of electrodes electrically connected to the first semiconductor film and a pair of electrodes electrically connected to the second semiconductor film.

### BRIEF DESCRIPTION OF DRAWINGS

FIG. 1 is a schematic cross-sectional view of a CMOS circuit according to an embodiment of the present invention.

FIG. 2 is a schematic cross-sectional view showing a fabrication method of a CMOS circuit according to an embodiment of the present invention.

FIG. 3 is a schematic cross-sectional view showing a fabrication method of a CMOS circuit according to an embodiment of the present invention.

FIG. 4 is a schematic cross-sectional view showing a fabrication method of a CMOS circuit according to an embodiment of the present invention.

FIG. 5 is a schematic cross-sectional view showing a fabrication method of a CMOS circuit according to an embodiment of the present invention.

FIG. 6 is a schematic cross-sectional view showing a fabrication method of a CMOS circuit according to an embodiment of the present invention.

FIG. 7 is a schematic cross-sectional view showing a fabrication method of a CMOS circuit according to an embodiment of the present invention.

FIG. 8 is a schematic cross-sectional view showing a fabrication method of a CMOS circuit according to an embodiment of the present invention.

FIG. 9 is a schematic cross-sectional view showing a fabrication method of a CMOS circuit according to an embodiment of the present invention.

FIG. 10 is a schematic cross-sectional view showing a fabrication method of a CMOS circuit according to an embodiment of the present invention.

FIG. 11 is a schematic cross-sectional view showing a fabrication method of a CMOS circuit according to an embodiment of the present invention.

FIG. 12 is a schematic cross-sectional view showing a fabrication method of a CMOS circuit according to an embodiment of the present invention.

FIG. 13 is a schematic cross-sectional view showing a fabrication method of a CMOS circuit according to an embodiment of the present invention.

FIG. 14 is a schematic cross-sectional view showing a fabrication method of a CMOS circuit according to an embodiment of the present invention.

FIG. 15 is a schematic top view of an electronic device according to an embodiment of the present invention.

FIG. 16 is a schematic cross-sectional view of an electronic device according to an embodiment of the present invention.

FIG. 17 is a schematic cross-sectional view showing a fabrication method of a pMOSTFT of a comparative example.

FIG. 18 is a schematic cross-sectional view showing a fabrication method of a pMOSTFT of a comparative example.

FIG. 19A shows V_{g}-I_{d} curves of the pMOSTFT of the comparative example.

FIG. 19B shows V_{g}-I_{d} curves of the pMOSTFT of the example.

### DESCRIPTION OF EMBODIMENTS

Hereinafter, each embodiment of the present invention is explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate. Similarly, the reference number is used when plural structures which are the same as or similar to each other are collectively represented, while a hyphen and a natural number are further used when these structures are independently represented.

In the specification and the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

In the specification and the claims, an expression “a structure is exposed from another structure” means a mode in which a part of the structure is not covered by the other structure and includes a mode where the part uncovered by the other structure is further covered by another structure. In addition, a mode expressed by this expression includes a mode where a structure is not in contact with other structures.

In the present invention, when a film is processed to form a plurality of films, these films may have different functions and roles. However, the plurality of films originates from a film prepared as the same layer in the same process and have substantially the same layer structure, the same material, and the same morphology. Hence, these films are defined as existing in the same layer.

### First Embodiment

In this embodiment, a CMOS circuit according to an embodiment of the present invention and a fabrication method of the same are explained.

### 1. Structure of CMOS Circuit

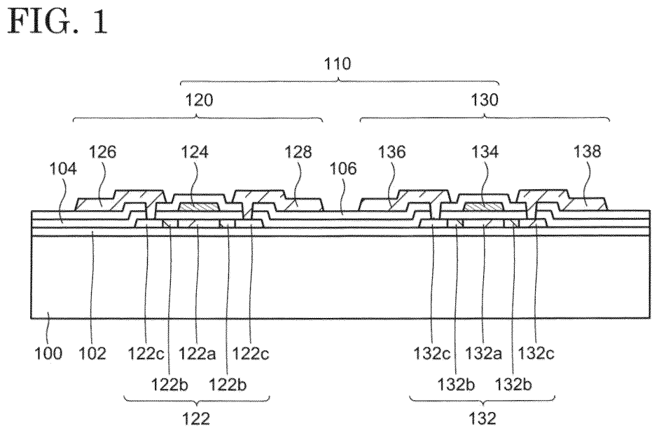

FIG. 1 shows a schematic cross-sectional view of the CMOS circuit 110. As shown in FIG. 1, the CMOS circuit 110 includes an nMOSTFT 120 and a pMOSTFT 130 disposed over the substrate 100 via an undercoat 102. The nMOSTFT 120 includes a semiconductor film 122, a gate insulating film 104 over the semiconductor film 122, a gate electrode 124 over the gate insulating film 104, an interlayer insulating film 106 covering the gate electrode 124, and a pair of terminals 126 and 128 provided over the interlayer insulating film 106 and electrically connected to the semiconductor film 122. One of the pair of terminals 126 and 128 functions as a source electrode, while the other functions as a drain electrode. Similarly, the pMOSTFT 130 includes a semiconductor film 132, the gate insulating film 104 over the semiconductor film 132, a gate electrode 134 over the gate insulating film 104, the interlayer insulating film 106 covering the gate electrode 134, and a pair of terminals 136 and 138 provided over the interlayer insulating film 106 and electrically connected to the semiconductor film 132. One of the pair of terminals 136 and 138 also functions as a source electrode, while the other functions as a drain electrode. The gate insulating film 104 and the interlayer insulating film 106 are shared by the nMOSTFT 120 and the pMOSTFT 130. Hereinafter, these configurations are described.

### (1) Substrate and Undercoat

The substrate 100 is a base material providing a surface for structuring the CMOS circuit 110 and mechanical strength to the electronic device in which the CMOS circuit 110 is incorporated. As the substrate 100, a glass substrate and a quartz substrate are exemplified, and a substrate containing a polymer such as a polyimide, a silicon substrate, a gallium substrate, a sapphire substrate, and the like may also be used. The substrate 100 may be flexible.

The undercoat 102 is a protective film to prevent impurities such as metal ions contained in the substrate 100 from entering the CMOS circuit 110 side and is composed of one or a plurality of films containing a silicon-containing inorganic compound such as silicon oxide, silicon nitride, silicon oxynitride, and silicon nitride oxide. The thickness of the undercoat 102 may be arbitrarily determined and may be selected from a range equal to or greater than 50 nm and equal to or less than 1000 nm, for example. Due to the fabrication method of the CMOS circuit 110 described below, the undercoat 102 may contain fluorine ions. Alternatively, the undercoat 102 may contain boron ions and fluorine ions.

### (2) Semiconductor Film

The semiconductor film 122 structuring the nMOSTFT 120 is a film including silicon and having polycrystalline morphology. The thickness of the semiconductor film 122 may be selected from a range equal to or greater than 20 nm and equal to or less than 100 nm, for example. The semiconductor film 122 has a channel region 122a overlapping the gate electrode 124 in the normal direction of the substrate 100, a pair of low-concentration impurity regions 122b sandwiching the channel region 122a, and a pair of source/drain regions 122c sandwiching the low-concentration impurity regions 122b. The channel region 122a includes a dopant imparting p-type conductivity (e.g., boron ions, aluminum ions, and the like). On the other hand, the low-concentration impurity regions 122b and the source/drain regions 122c contain a dopant imparting p-type conductivity (e.g., phosphorus ions, arsenic ions, antimony ions, nitrogen ions, and the like) as well as a dopant imparting n-type conductivity at a higher concentration than the dopant imparting p-type conductivity. Since the source/drain regions 122c have a higher dopant concentration compared with the low-concentration impurity regions 122b, the source/drain regions 122c have higher conductivity than the low-concentration impurity regions 122b. The source/drain regions 122c are also referred to as high-concentration impurity regions.

Similarly, the semiconductor film 132 structuring the pMOSTFT 130 also contains silicon and has polycrystalline morphology. As described below, the semiconductor films 122 and 132 are obtained by simultaneously crystallizing an amorphous silicon film formed in the same process, and therefore, their thicknesses and morphology are substantially identical. The semiconductor film 132 also has a channel region 132a overlapping the gate electrode 134 in the normal direction of the substrate 100, a pair of low-concentration impurity regions 132b sandwiching the channel region 132a, and a pair of source/drain regions (also called high-concentration impurity regions) 132c sandwiching the low-concentration impurity regions 132b. The channel region 132a and the low-concentration impurity regions 132b contain the aforementioned dopant imparting p-type conductivity. However, unlike the nMOSTFT 120, the source/drain regions 132c contain fluorine ions in addition to boron ions. Furthermore, fluorine ions may be selectively included in the source/drain regions 132c without being included in the low-concentration impurity regions or may be included in both the source/drain regions 132c and the low-concentration impurity regions 132b. When fluorine ions are included in both the source/drain regions 132c and the low-concentration impurity regions 132b, the fluorine ion concentration may be substantially the same between the low-concentration impurity regions 132b and the source/drain regions 132c, or the fluorine ion concentration in the latter may be higher than in the former. The fluorine ion concentration in the source/drain regions 132c is, for example, equal to or greater than 1×10¹⁸ atoms/cm³ and equal to or less than 5×10²⁰ atoms/cm³. The concentration of the dopants in the source/drain regions 132c is higher than that in the low-concentration impurity regions 132b, resulting in higher conductivity of the source/drain regions 132c than the low-concentration impurity regions 132b.

### (3) Gate Insulating Film

The gate insulating film 104 is composed of one or a plurality of films containing the aforementioned silicon-containing inorganic compound. The thickness of the gate insulating film 104 may be selected from a range equal to or greater than 2 nm and equal to or less than 200 nm, for example. Alternatively, the gate dielectric film 104 may be configured to include so-called high-k materials such as hafnium silicate, hafnium silicate containing nitrogen, hafnium oxide, nitrogen-doped hafnium aluminate, and yttrium oxide.

### (4) Gate Electrode

The gate electrodes 124 and 134 include a metal (0-valent metal) such as molybdenum, tungsten, titanium, aluminum, and copper or an alloy containing at least one of these metals and are provided to respectively overlap the channel regions 124a and 132a. In the nMOSTFT 120, the low-concentration impurity regions 122b and the source/drain regions 122c are exposed from gate electrode 124, and similarly, the low-concentration impurity regions 132b and the source/drain regions 132c are exposed from gate electrode 134 in the pMOSTFT 130. As described below, the compositions and the thicknesses of the gate electrodes 124 and 134 are substantially identical to each other because they can exist in the same layer. The thicknesses of the gate electrodes 124 and 134 may be, for example, equal to or greater than 20 nm and equal to or less than 500 nm.

### (5) Interlayer Insulating Film

The interlayer insulating film 106 is a component to electrically insulate the pair of terminals 126, 128 and the gate electrode 124 from each other and the pair of terminals 136, 138 and the gate electrode 134 from each other, and may be composed of one or a plurality of films containing the silicon-containing inorganic compound described above. The thickness of the interlayer insulating film 106 is also arbitrary and may be selected from a range equal to or greater than 100 nm and equal to or less than 1000 nm, for example.

### (6) Terminal

Similar to the gate electrodes 124 and 134, the pair of terminals 126 and 128 and the pair of terminals 136 and 138 also include the aforementioned metal or alloy and are electrically connected to the semiconductor films 122 and 132, respectively, through the openings formed in the interlayer dielectric film 106. Although not illustrated, a portion of the terminal 126 and a portion of the terminal 128 may overlap the gate electrode 124. Similarly, a portion of the terminal 136 and a portion of the terminal 138 may also overlap the gate electrode 134. Since these terminals 126, 128, 136, and 138 can also exist in the same layer, the compositions and the thicknesses are substantially identical to each other. The thicknesses of the terminals 126, 128, 136, 138 may be set to be equal to or greater than 20 nm and equal to or less than 500 nm, for example. Although not illustrated in FIG. 1, one of the terminals 126 and 128 is electrically connected to one of the terminals 136 and 138.

Due to the fabrication method of the CMOS circuit 110 described below, the semiconductor films 122 and 132 structuring the nMOSTFT 120 and the pMOSTFT 130 both suffer less damage during dopant injection and have fewer crystal defects. Hence, the characteristics of the nMOSTFT 120 and the pMOSTFT 130, especially the S values indicating the sub-threshold characteristics, are small. In addition, since the damage to the gate insulating film 104 caused by the dopant injection is also reduced, this leads to a decrease in defects at the interface between the gate insulating film 104 and the semiconductor film 122 and at the interface between the gate insulating film 104 and the semiconductor film 132. As a result, the nMOSTFT 120 and the pMOSTFT 130 exhibit excellent characteristics and high reliability. Therefore, a variety of circuits including the CMOS circuit 110 is also able to exhibit excellent characteristics and high reliability.

### 2. Manufacturing Method of CMOS Circuit

Hereinafter, a fabrication method of the CMOS circuit 110 is described.

### (1) Formation of Semiconductor Film

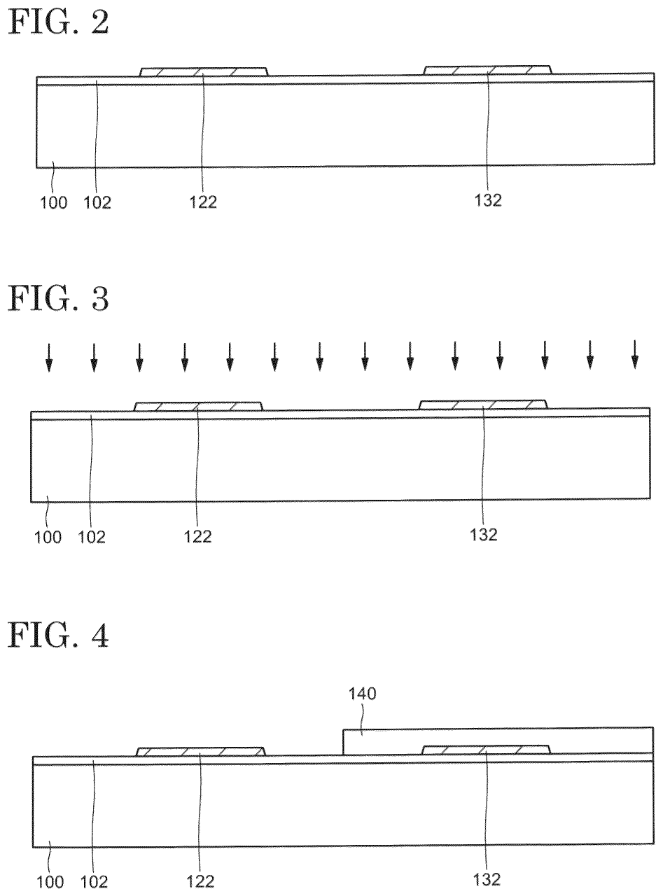

First, the undercoat 102 is formed over the substrate 100, over which a plurality of polysilicon films arranged in an island shape is formed to form the semiconductor films 122 and 132 respectively structuring the nMOSTFT 120 and the pMOSTFT 130 (FIG. 2). Since the process up to this point can be carried out by applying known methods, a detailed description is omitted. In brief, the undercoat 102 is formed over the substrate 100 using a chemical vapor deposition (CVD) method or a sputtering method. The CVD method is then used to form an amorphous silicon film over the undercoat 102. The amorphous silicon film is subjected to heat treatment or laser irradiation, which converts the amorphous silicon film into a polysilicon film. The polysilicon film is then patterned by photolithography to obtain the semiconductor films 122 and 132.

### (2) Formation of Channel Region

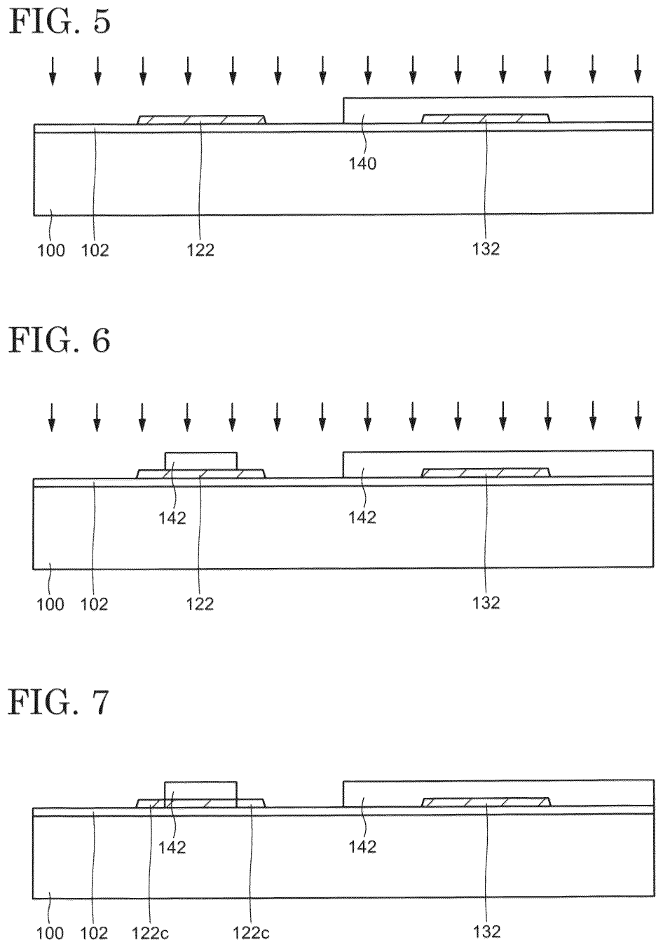

Subsequently, p doping is performed on the semiconductor films 122 and 132 (FIG. 3). In this process, a mass separation type ion-implantation apparatus may be used to inject boron ions (B⁺) or aluminum ions (Al³⁺) into the semiconductor films 122 and 132. When the dopant is boron ions, the dosage may be, for example, equal to or greater than 1×10¹¹ atoms/cm² and equal to or less than 1×10¹³ atoms/cm². The semiconductor film 132 is then protected with a resist film 140 (FIG. 4), and a dopant imparting p-type conductivity, such as boron ions, are further injected into the semiconductor film 122 providing the nMOSTFT 120 (FIG. 5). The dosage at this time may be, for example, equal to or greater than 5×10¹¹ atoms/cm² and equal to or less than 5×10¹² atoms/cm² when the dopant is boron ions. The resist film 140 is then removed by ashing or other means. Note that the semiconductor films 122 and 132 may be heat treated to activate the injected ions. As a result of the above process, the semiconductor films 122 and 132 respectively obtain the compositions of the channel regions 122a and 132a.

### (3) Formation of Source/Drain Region

Subsequently, the source/drain regions 122c and 132c are formed in the semiconductor films 122 and 132, respectively. Specifically, a resist film 142 is formed to cover the entire semiconductor film 132 and a portion of the semiconductor film 122 as shown in FIG. 6. Over the semiconductor film 122, the resist film 142 is provided to expose the portions where the source/drain regions 122c are formed. As a result, the resist film 142 exposes both edge portions of the semiconductor film 122 and masks the region sandwiched between these edge portions and the entire semiconductor film 132.

Then, an ion implantation apparatus is used to inject a dopant imparting n-type conductivity, such as phosphorus ions (FIG. 6). As a result, the dopant is selectively and directly injected into both edge portions of the semiconductor film 122 exposed from the resist film 142 without any other component (e.g., the gate insulating film 104 and the like), resulting in the formation of the pair of source/drain regions 122c sandwiching the channel region 122a (FIG. 7). The resist film 142 is then removed and, if necessary, heat treatment is performed to activate the dopant.

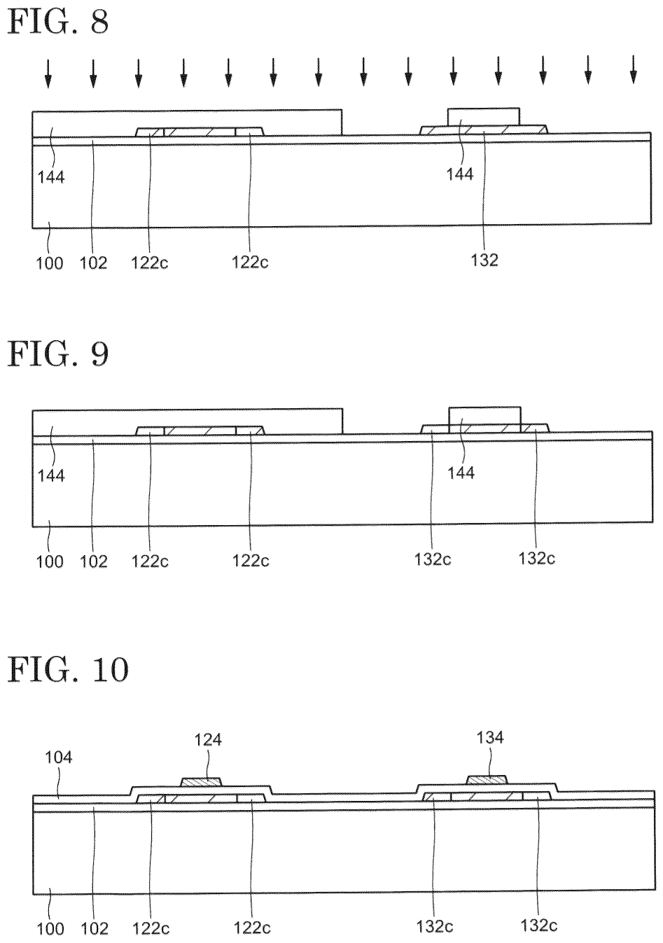

As shown in FIG. 8, a resist film 144 is subsequently formed to cover the entire semiconductor film 122 and a portion of the semiconductor film 132. Over the semiconductor film 132, the resist film 144 is provided to expose the portions where the source/drain regions 132c are to be formed. With this process, the resist film 144 exposes both edge portions of the semiconductor film 132 and masks a region sandwiched between these two edge portions and the entire semiconductor film 122.

Then, an ion implantation apparatus is used to inject a dopant imparting p-type conductivity (FIG. 8). The dopant used at this time is ions containing boron and fluorine, and BF⁺, BF₂⁺, and/or BF₃⁺ is specifically used. With this process, the dopant is selectively and directly injected into both edge portions of the semiconductor film 132 exposed from the resist film 144 without any other configuration (e.g., the gate insulating film 104 and the like), resulting in the formation of the pair of source/drain regions 132c sandwiching the channel region 132a (FIG. 9). Moreover, the process allows the source/drain regions 132c to contain fluorine ions along with boron ions. Note that the dopant may also be injected into the undercoat 102 exposed from the semiconductor film 132 during the ion injection. Therefore, the undercoat 102 may also contain boron ions and/or fluorine ions. The resist film 144 is then removed by ashing or the like. If necessary, heat treatment may be performed to activate the dopants.

In the above explanation, the source/drain regions 122c are formed first, and then the source/drain regions 132c are formed. However, the source/drain regions 132c may be formed first, and then the source/drain regions 122c may be formed.

As described above, in the doping process to form the source/drain regions 122c and 132c, ions are injected directly into the semiconductor films 122 and 132 without any other configuration such as the gate insulating film 104. Thus, the dosage can be reduced. For example, the ion injection can be performed with the dosage equal to or greater than 1×10¹⁴ atoms/cm² and equal to or smaller than 1×10¹⁵ atoms/cm². Furthermore, since direct ion injection is performed, the acceleration voltage of the ions can be kept low, and damage to the semiconductor films 122 and 132 caused by the ion injection can be suppressed. In addition, since the gate insulating film 104 is absent in this process, defect formation at the interface between the gate insulating film 104 and the semiconductor film 122 and at the interface between the gate insulating film 104 and the semiconductor film 132 due to the ion injection can be ignored. These features contribute to improved characteristics and reliability of the CMOS circuit 110. In addition, since the load on the ion implantation apparatus is reduced and the ion injection time can be reduced, the lifetime of the ion implantation apparatus can be extended and the frequency and cost of maintenance can be reduced. Therefore, the CMOS circuit 110 can be fabricated at a lower cost.

### (4) Formation of Gate Insulating Film and Gate Electrode

Next, the gate insulating film 104 is formed to cover the semiconductor films 122 and 132, and then the gate electrodes 124 and 134 are formed over the gate insulating film 104 so as to respectively overlap the semiconductor films 122 and 132 (FIG. 10). Since the gate insulating film 104 and the gate electrodes 124 and 134 can be formed by applying known methods, a detailed description is omitted. In brief, the gate insulating film 104 may be formed by applying a CVD method using a tetraalkoxysilane exemplified by tetraethoxysilane as a raw material. The gate electrodes 124 and 134 may be formed by forming a film including the above-mentioned metal or alloy over the gate insulating film 104 with a CVD method or a sputtering method, followed by conducting patterning by photolithography. Note that the gate electrode 124 is provided so as not to overlap the source/drain regions 122c and to be spaced away from the source/drain regions 122c when viewed from the top surface of the substrate 100. Similarly, the gate electrode 134 is formed so as not to overlap the source/drain regions 132c and to be spaced away from the source/drain regions 132c when viewed from the top surface of the substrate 100.

### (5) Formation of Low-Concentration Impurity Region

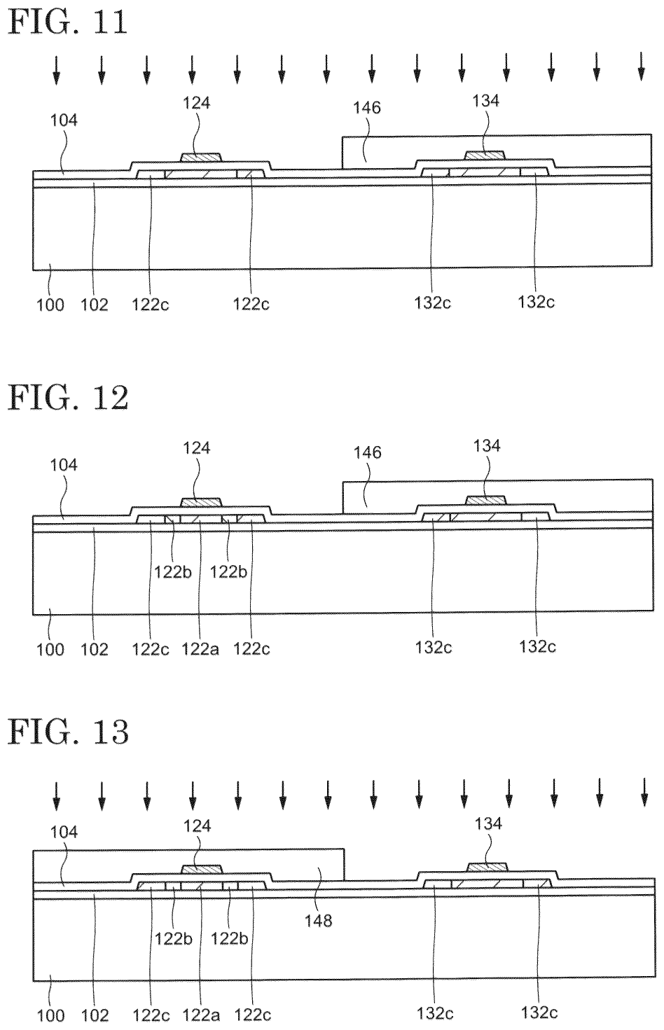

After that, the low-concentration impurity regions 122b and 132b are formed. Specifically, a resist film 146 covering the semiconductor film 132 is formed, and an ion implantation apparatus is used to inject a dopant imparting n-type conductivity into the semiconductor film 132 through the gate insulating film 104 as shown in FIG. 11. At this time, since the gate electrode 124 also functions as a mask, the dopant is injected not only into the source/drain regions 122c but also between a region overlapping the gate electrode 124 (i.e., the channel region 122a) and the source/drain regions 122c. As a result, in addition to the channel region 122a, the low-concentration impurity regions 122b having a lower ion concentration than the source/drain regions 122c is formed between the channel region 122a and the source/drain regions 122c (FIG. 12). Note that the dopant used at this time may be the same as or different from the dopant used to form the source/drain regions 122c.

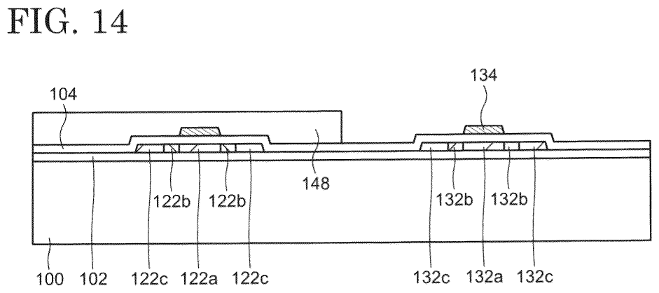

The resist film 146 is then removed, and a resist film 148 covering the semiconductor film 122 is formed. Furthermore, an ion implantation apparatus is used to inject a dopant imparting p-type conductivity into the semiconductor film 132 through the gate insulating film 104 (FIG. 13). At this time, since the gate electrode 134 also functions as a mask, the dopant is injected between a region overlapping the gate electrode 134 (i.e., the channel region 132a) and the source/drain regions 132c in addition to the source/drain regions 132c. The dopant used at this time may be the same as or different from the dopant used to form the source/drain regions 132c. Thus, the dopant may be boron ions or aluminum ions or may be BF⁺, BF₂⁺, or BF₃⁺. With the above process, the low-concentration impurity regions 132b having a lower ion concentration than the source/drain regions 132c are formed between the channel region 132a and the source/drain regions 132c along with the channel region 132a (FIG. 14). The resist film 148 is then removed.

In the above description, the low-concentration impurity regions 132b are formed after the low-concentration impurity regions 122b are formed. However, there is no limitation on the order of formation of these regions, and the former may be formed after the latter is formed. If necessary, heat treatment may be performed to activate the dopant.

### (6) Formation of Interlayer Insulating Film and Terminals

The CMOS circuit 110 shown in FIG. 1 is fabricated by forming the interlayer insulating film 106 and the terminals 126, 128, 136, and 138. Since the interlayer insulating film 106 and the terminals 126, 128, 136, and 138 can be formed by applying known methods, a detailed description is omitted. In brief, the interlayer insulating film 106 may be formed to cover the gate electrodes 124 and 134 and the gate insulating film 104 using a CVD method. The interlayer insulating film 106 and the gate insulating film 104 are then processed with etching to form the openings exposing portions of the source/drain regions 122c and 132c. Further, a metal film including the metal or alloy described above is formed over the interlayer insulating film 106 to fill the openings, and then the metal film is processed by photolithography to form the terminals 126, 128, 136, and 138.

As described above, in the fabrication method of the CMOS circuit 110 according to an embodiment of the present invention, the ion injection is performed on the semiconductor films 122 and 132 without passing through the gate insulating film 104 during the doping process to form the source/drain regions 122c and 132c. Therefore, the acceleration voltage and the dosage of the dopant ions can be suppressed, and ion injection damage to the semiconductor films 122 and 132 can be reduced. In addition, because doping through the gate insulating film 104 is limited to the process of forming the low-concentration impurity regions 122b and 132b, the probability of defect generation at the interface between the gate insulating film 104 and the semiconductor film 122 and at the interface between the gate insulating film 104 and the semiconductor film 132 is low. These features allow the production of the nMOSTFT 120 and the pMOSTFT 130 having excellent characteristics and high reliability as well as the CMOS circuit 110 including these components.

### Second Embodiment

In this embodiment, an electronic device including the CMOS circuit 110 described in the First Embodiment is explained. An explanation of the structures the same as or similar to those described in the First Embodiment may be omitted.

There are no restrictions on electronic devices including the CMOS circuit 110, and a display device such as a liquid crystal display and an electroluminescence display device, a photoelectric conversion device exemplified by an image-capturing device are represented. Hereinafter, an electroluminescence display device provided with organic electroluminescence elements as display elements is explained as an example of display devices.

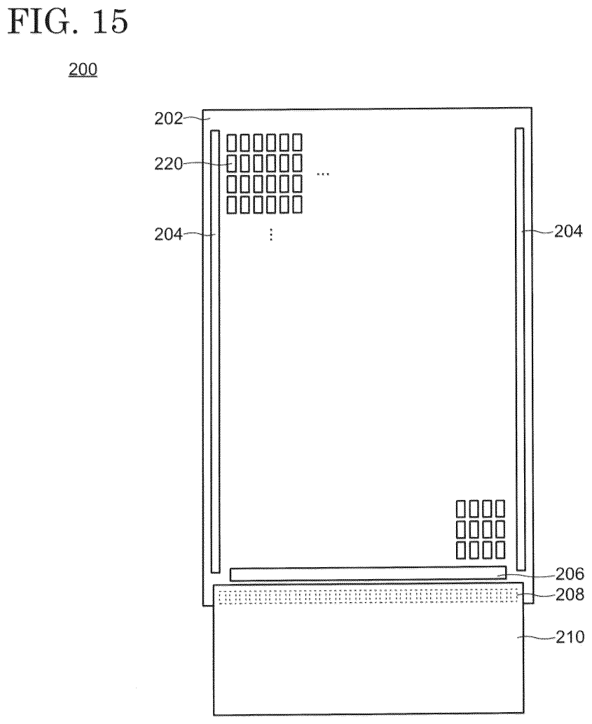

A schematic top view of a display device 200 which is an electronic device according to an embodiment of the invention is shown in FIG. 15. As shown in FIG. 15, the display device 200 has a substrate 202, over which a variety of patterned insulating films, semiconductor films, and conductor films is stacked. A plurality of pixels 220 and driver circuits for driving the pixels 220 (scanning-line driver circuit 204, signal-line driver circuit 206) are fabricated over the substrate 20 by appropriately stacking these films over the substrate 202. A counter substrate which is not illustrated in FIG. 15 is provided over the pixels 220, the scanning-line driver circuit 204, and the signal-line driver circuit 206, and the pixels 220, the scanning-line driver circuit 204, and the signal-line driver circuit 206 are sealed and protected by the substrate 202 and the counter substrate. A plurality of terminals 208 fabricated with a conductor film are formed over the substrate 202, and the terminals 208 are electrically connected to an external circuit, which is not illustrated, via a connector 210 such as a flexible printed circuit (FPC) board. A variety of signals and power for displaying images are supplied from the external circuit to the scanning-line driver circuit 204 and the signal-line driver circuit 206 through the terminals 208. Note that either or both of the scanning-line driver circuit 204 and the signal-line driver circuit 206 need not be formed directly over the substrate 202, and a driver circuit formed over a substrate different from the substrate 202 (such as a semiconductor substrate) may be mounted over the substrate 202 or the connector.

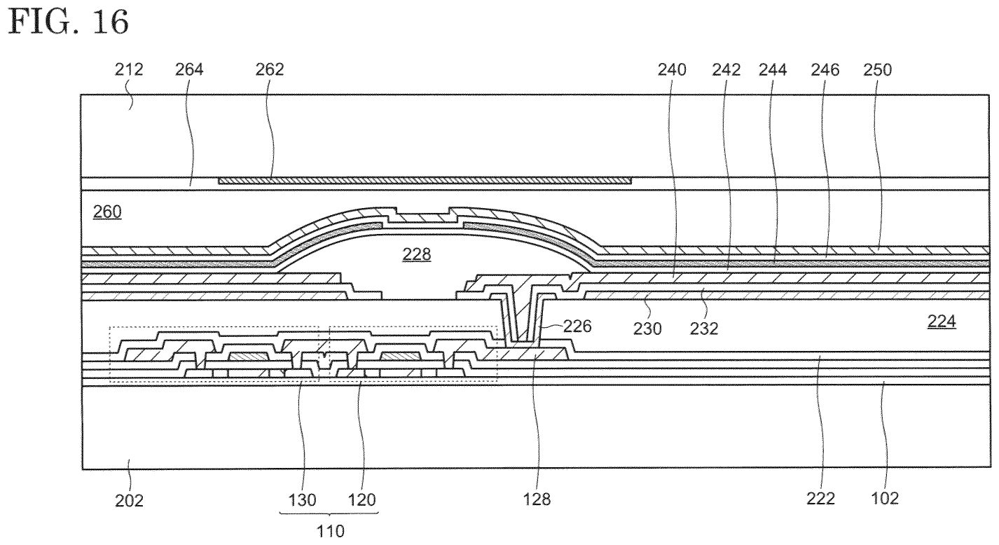

The CMOS circuit 110 may be incorporated in any of the scanning-line driver circuit 204, the signal-line driver circuit 206, and the pixels 220. As an example, a schematic cross-sectional view of a portion of the pixel 220 in which the CMOS circuit 110 is incorporated is shown in FIG. 16. As shown in FIG. 16, the undercoat 102 is provided over the substrate 202 corresponding to the substrate 100, and the CMOS circuit 110 is provided over the undercoat 102. A leveling film 224 is formed over the CMOS circuit 110 to absorb irregularities caused by the CMOS circuit 110 and provide a flat surface. As an optional component, a protective insulating film 222 may be disposed between the CMOS circuit 110 and the leveling film 224 to prevent entrance of impurities from the leveling film 224.

An opening is formed in the leveling film 224 and the protective insulating film 222 to expose one terminal 128 of the nMOSTFT 120, through which the pixel electrode 240 is directly connected to the terminal 128 or electrically connected to the terminal 128 through a connecting electrode 226 which is an optional component. In each pixel 220, a supplemental capacitance electrode 230 may be provided over the leveling film 224, over which the pixel electrode 240 may be placed via a capacitance insulating film 232. This structure allows the formation of a supplemental capacitance composed of the supplemental capacitance electrode 230, the capacitance insulating film 232, and the pixel electrode 240, and the potential of a variety of signals such as video signals supplied from the signal-line driver circuit 206 can be more securely held by using this supplemental capacitance.

The organic electroluminescence element serving as a display element is composed of the pixel electrode 240, a common electrode 250 over the pixel electrode 240, and a plurality of functional layers therebetween. The number and types of functional layers are not limited, and charge-injection layers, charge-transporting layers, charge-blocking layers, exciton-blocking layers, and emission layers may be used as appropriate. In FIG. 15, a hole-transporting layer 242, an emission layer 244, and an electron-transport layer 246 are illustrated for visibility. Note that a bank 228 is provided at the edge of the pixel electrode 240, by which the adjacent pixels 220 are electrically insulated and disconnection of the functional layers is prevented.

A sealing film 260 may be provided over the organic electroluminescence elements to protect the organic electroluminescence elements. A light-shielding film 262 for covering the space between adjacent pixels 220 and an overcoat 264 covering the light-shielding film 262 may be disposed over the counter substrate 212.

As described in the First Embodiment, since the CMOS circuit 110 exhibits excellent characteristics and high reliability, incorporation of the CMOS circuit 110 into the scanning-line driver circuit 204 and/or the signal-line driver circuit 206 allows the display device 200 to obtain high operation speed. In addition, a circuit with excellent switching characteristics can be constructed in each pixel 220 by incorporating the CMOS circuit 110 in the pixels 220.

### Examples

In this Example, a pMOSTFT included in the CMOS circuit according to an embodiment of the present invention was fabricated, and the results of evaluating the characteristics thereof are described.

1. Fabrication of pMOSTFT

The pMOSTFT was fabricated according to the method described in the First Embodiment. Specifically, a silicon nitride film (50 nm) and a silicon oxide film (100 nm) were sequentially formed over a glass substrate using a CVD method to form an undercoat, over which an amorphous silicon film (50 nm) was prepared using a CVD method. The amorphous silicon was processed into a rectangular shape by photolithography. A semiconductor film containing polysilicon was formed by irradiating the processed amorphous silicon with a linearly processed excimer laser. Then, an ion implantation apparatus was used to inject boron ions with an energy of 5 keV into the semiconductor film at a dose of 1×10¹² atoms/cm², and heat treatment was further carried out.

Sequentially, a resist film was formed over the semiconductor film to expose both edge portions of the semiconductor film, and an ion implantation apparatus was used to inject BF₂⁺ with an energy of 10 keV into both edge portions exposed from the resist film at a dose of 5×10¹⁴ atoms/cm². After removal of the resist film, heat treatment was performed, and a 100 nm thick silicon oxide film was further formed as the gate insulating film using a CVD method. Furthermore, a gate electrode containing an alloy of molybdenum and tantalum was formed over the gate insulating film at a thickness of 250 nm. Then, boron ions with an energy of 52 keV were injected into the semiconductor film at a dose of 3×10¹³ atoms/cm² using the gate electrode as a mask, and heat treatment was conducted.

Then, a silicon oxide film was formed as the interlayer insulating film covering the gate electrode and the gate insulating film with a CVD method. The pMOSTFT of the Example was fabricated by dry-etching the interlayer insulating film to form an opening, followed by forming a pair of terminals containing an alloy of molybdenum and tantalum thereover.

### 2. Fabrication of Comparative Example

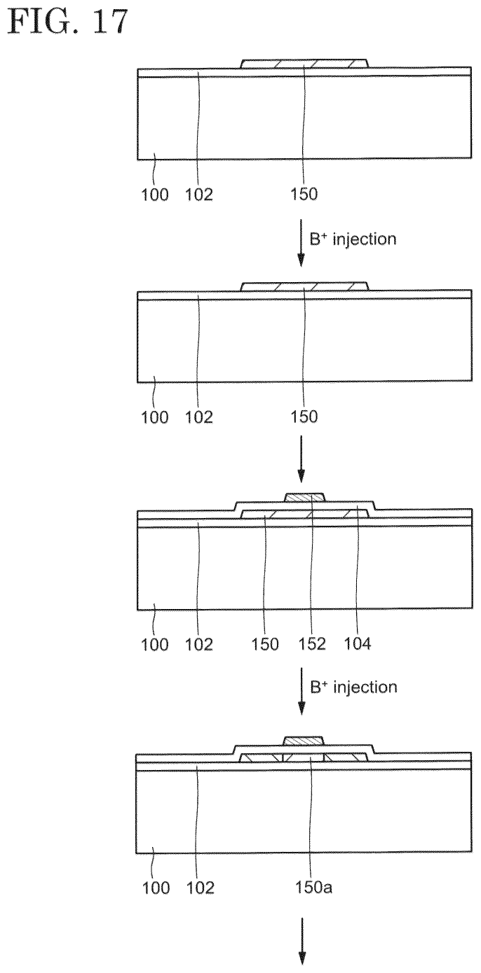

As a Comparative Example, a thin-film transistor with the same structure as the pMOSTFT of the Example was fabricated. However, unlike the Example, the gate insulating film and the gate electrode were formed after the first boron ion doping, and then the second boron ion doping was carried out. Specifically, similar to the Example, an ion implantation apparatus was used to inject boron ions with an energy of 5 keV into a polysilicon-containing semiconductor film 150 formed over an undercoat 102 prepared over the substrate 100, which is a glass substrate, so that the dosage reached 1×10¹² atoms/cm² as shown in FIG. 17. After heat treatment, a 100 nm thick silicon oxide film was formed as a gate insulating film 104 using a CVD method, and a gate electrode 152 containing an alloy of molybdenum and tantalum was formed thereover. Then, boron ions with an energy of 52 keV were injected into the semiconductor film 150 at a dose of 3×10¹³ atoms/cm² using the gate electrode 124 as a mask. At this stage, a channel region 150a was formed in the region overlapping the gate electrode 124.

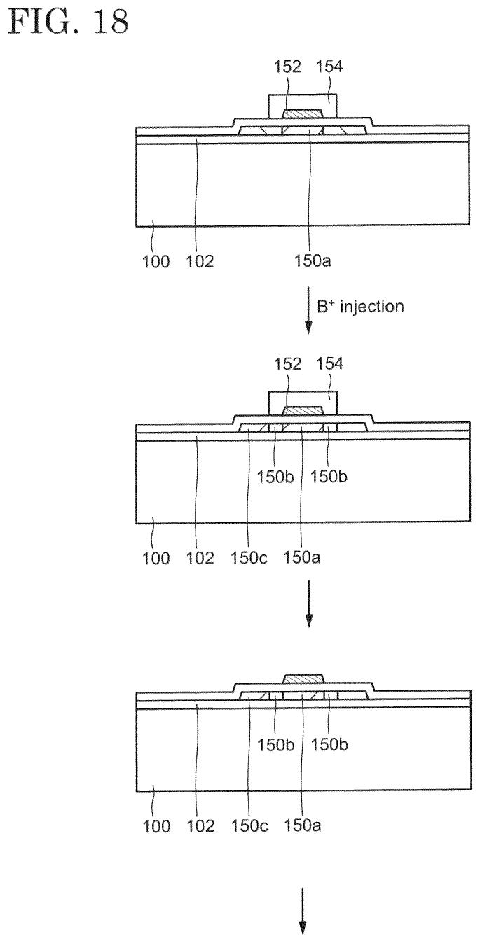

As shown in FIG. 18, a resist film 154 was then formed to cover the gate electrode 124 and partially cover a portion exposed from the gate electrode 152, and boron ions with an energy of 52 keV were injected into the semiconductor film 150 at a high dosage (3×10¹⁵ atoms/cm²). With this process, the source/drain regions 150c in the regions exposed from the resist film 154 were formed, and the low-concentration impurity regions 150b were formed in a region which does not overlap the gate electrode but is covered by the resist film 154 (i.e., the regions sandwiched by the channel region 150a and the source/drain regions 150c). After the resist film 154 was removed, heat treatment was carried out to result in the pMOSTFT.

### 3. Evaluation

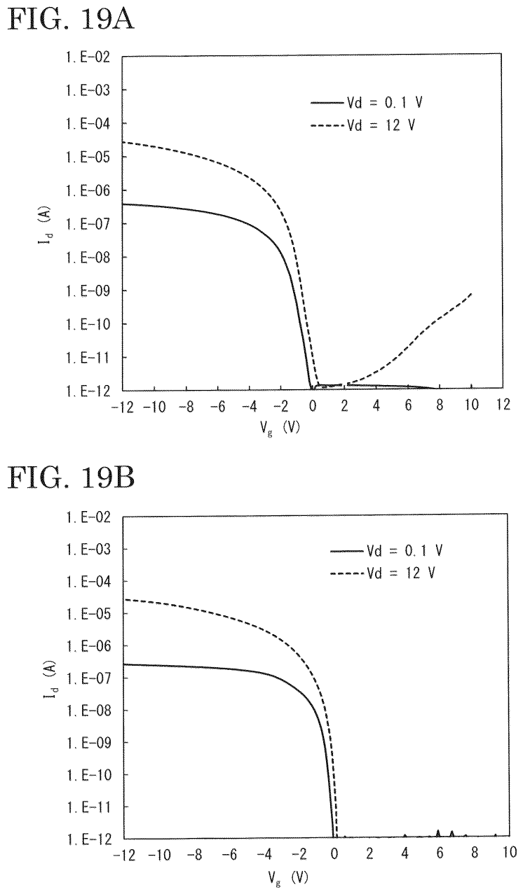

The V_{g}-I_{d} curves (source-drain voltage (V_{SD}) 12V) of the pMOSTFTs of the Comparative Example and Example are shown in FIG. 19A and FIG. 19B, respectively. From these results, it can be understood that the S value of the Example is improved compared with the Comparative Example.

The above results indicate that pMOSTFTs with excellent switching characteristics can be provided by applying the fabrication method of the CMOS circuits according to an embodiment of the present invention.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process on the basis of each embodiment is included in the scope of the present invention as long as they possess the concept of the present invention.

It is understood that another effect different from that provided by each of the aforementioned embodiments is achieved by the present invention if the effect is obvious from the description in the specification or readily conceived by persons ordinarily skilled in the art.

What is claimed is:

1. A complementary metal-oxide semiconductor circuit comprising:
a n-type metal-oxide semiconductor thin-film transistor and a p-type metal-oxide semiconductor thin-film transistor each comprising:
a semiconductor film;
a gate insulating film over the semiconductor film;
a gate electrode over the gate insulating film;
an interlayer insulating film over the gate electrode; and
a pair of terminals located over the interlayer insulating film and electrically connected to the semiconductor film,
wherein the semiconductor film of the p-type metal-oxide semiconductor thin-film transistor includes a fluorine ion.

2. The complementary metal-oxide semiconductor circuit according to claim 1,
wherein, in each of the n-type metal-oxide semiconductor thin-film transistor and the p-type metal-oxide semiconductor thin-film transistor, the semiconductor film comprises:
a channel region overlapping the gate electrode;
a pair of low-concentration impurity regions sandwiching the channel region; and
a pair of source/drain regions sandwiching the pair of low-concentration impurity regions.

3. The complementary metal-oxide semiconductor circuit according to claim 1,
wherein a concentration of the fluorine ion in the semiconductor film of the p-type metal-oxide semiconductor thin-film transistor is equal to or greater than 1×10¹⁵ atoms/cm³ and equal to or less than 1×10²⁰ atoms/cm³.

4. The complementary metal-oxide semiconductor circuit according to claim 2,
wherein the fluorine ion is selectively included in the source/drain regions of the p-type metal-oxide semiconductor thin-film transistor.

5. The complementary metal-oxide semiconductor circuit according to claim 1, further comprising an undercoat under the n-type metal-oxide semiconductor thin-film transistor and the p-type metal-oxide semiconductor thin-film transistor,
wherein the undercoat includes the fluorine ion.

6. An electronic device comprising a complementary metal-oxide semiconductor circuit comprising a n-type metal-oxide semiconductor thin-film transistor and a p-type metal-oxide semiconductor thin-film transistor each comprising:
a semiconductor film;
a gate insulating film over the semiconductor film;
a gate electrode over the gate insulating film;
an interlayer insulating film over the gate electrode; and
a pair or terminals located over the interlayer insulating film and electrically connected to the semiconductor film,
wherein the semiconductor film of the p-type metal-oxide semiconductor thin-film transistor includes a fluorine ion.

7. The electronic device according to claim 6,
wherein, in each of the n-type metal-oxide semiconductor thin-film transistor and the p-type metal-oxide semiconductor thin-film transistor, the semiconductor film comprises:
a channel region overlapping the gate electrode;
a pair of low-concentration impurity regions sandwiching the channel region; and
a pair of source/drain regions sandwiching the pair of low-concentration impurity regions.

8. The electronic device according to claim 6,
wherein a concentration of the fluorine ion in the semiconductor film of the p-type metal-oxide semiconductor thin-film transistor is equal to or greater than 1×10¹⁵ atoms/cm³ and equal to or less than 1×10²⁰ atoms/cm³.

9. The electronic device according to claim 7,
wherein the fluorine ion is selectively included in the source/drain regions of the p-type metal-oxide semiconductor thin-film transistor.

10. The electronic device according to claim 6, further comprising an undercoat under the n-type metal-oxide semiconductor thin-film transistor and the p-type metal-oxide semiconductor thin-film transistor,
wherein the undercoat includes the fluorine ion.

11. The electronic device according to claim 6,
wherein the electronic device is a display device.

12. A fabrication method of a complementary metal-oxide semiconductor circuit, the fabrication method comprising:
forming an undercoat over a substrate;
forming a first semiconductor film and a second semiconductor film over the undercoat;
doping both edge portions of the first semiconductor film with a first dopant imparting n-type conductivity in a state where the second semiconductor film and a region between both the edge portions of the first semiconductor film are masked;
doping both edge portions of the second semiconductor film with a second dopant imparting p-type conductivity in a state where the first semiconductor film and a region between both the edge portions of the second semiconductor film are masked;
forming a gate insulating film over the first semiconductor film and the second semiconductor film;
forming, over the gate insulating film, a first gate electrode overlapping the first semiconductor film and exposing both the edge portions of the first semiconductor film and a second gate electrode overlapping the second semiconductor film and exposing both the edge portions of the second semiconductor film;
forming an interlayer insulating film overlapping the first gate electrode and the second gate electrode; and
forming, over the interlayer insulating film, a pair of electrodes electrically connected to the first semiconductor film and a pair of electrodes electrically connected to the second semiconductor film.

13. The fabrication method according to claim 12,
wherein the second dopant includes boron and fluorine.

14. The fabrication method according to claim 12,
wherein the second dopant includes at least one of a BF²⁺ ion and a BF₂⁺ ion.

15. The fabrication method according to claim 12, further comprising:
doping the first semiconductor film with a third dopant imparting n-type conductivity using the first gate electrode as a mask; and
doping the second semiconductor film with a fourth dopant imparting p-type conductivity using the second gate electrode as a mask.

16. The fabrication method according to claim 15,
wherein the third dopant and the fourth dopant are the same as each other.

17. The fabrication method according to claim 12, further comprising doping the first semiconductor film and the second semiconductor film with a fifth dopant imparting p-type conductivity before the doping with the first dopant and the second dopant.

18. The fabrication method according to claim 13,
wherein the doping with the second dopant is performed such that a concentration of the fluorine ion in the second semiconductor film is equal to or greater than 1×10¹⁵ atoms/cm³ and equal to or less than 1×10²⁰ atoms/cm³.
